(19) United States
(12) Patent Application Publication
(10) Pub. No.: US 2026/0276105 A1
(43) Pub. Date: Sep. 17, 2026

(54) CLIP AND FLUID SUPPLY DEVICE INCLUDING CLIP

(71) Applicant: FUJIKIN INCORPORATED, Osaka (JP)

(72) Inventors: Takuya KUMAMOTO, Osaka (JP); Taiki HOSHIKO, Osaka (JP)

(73) Assignee: FUJIKIN INCORPORATED, Osaka (JP)

(21) Appl. No.: 19/166,867

(22) PCT Filed: Jan. 23, 2024
(86) PCT No.: PCT/JP2024/001761

§ 371 Date: Sep. 18, 2025

(30) Foreign Application Priority Data
Mar. 28, 2023 (JP) 2023-051366

(51) Int. Cl. F16L 3/04; F16L 3/00

(52) U.S. Cl. CPC F16L 3/04; F16L 3/006

(57) ABSTRACT

A heater-equipped clip attached to each of a plurality of fluid supply lines which are arranged side by side in a fluid supply device and each include a plurality of base blocks includes a plate portion including a fixed heater and formed to be surface-contactable with one side wall of the base block, a holding claw portion formed to be contactable with another side wall of the base block opposite to the one side wall, and a coupling mechanism configured to couple the plate portion and the holding claw portion.

### TECHNICAL FIELD

The present invention relates to a clip and a fluid supply device including a clip.

### BACKGROUND ART

JP2020-159445A discloses a heater fixture that clamps gas lines (that is, a fluid supply line) and heaters provided on both sides of the gas lines.

### SUMMARY OF INVENTION

However, since the heater fixture disclosed in JP 2020-159445A sandwiches the gas lines via the heaters, it is difficult to attach such a heater fixture to the gas lines when the gap between the gas lines is narrow.

The present invention has been made in view of this problem, and an object thereof is to provide a clip that can be attached even when a gap between fluid supply lines is narrow and a fluid supply device including the clip.

An aspect of the present invention provides a clip attached to each of a plurality of fluid supply lines which are arranged side by side in a fluid supply device and each include a plurality of flow passage blocks. The clip includes a plate portion including an integrally formed heater and formed to be surface-contactable with one side wall of the flow passage block, a holding claw portion formed to be contactable with another side wall of the flow passage block opposite to the one side wall, and a coupling mechanism configured to couple the plate portion and the holding claw portion.

Another aspect of the present invention provides a fluid supply device including: a plurality of fluid supply lines arranged side by side and each including a plurality of flow passage blocks; and a plurality of clips attached to the plurality of fluid supply lines, respectively. Each of the clips includes a plate portion including an integrally formed heater and formed to be surface-contactable with one side wall of the flow passage block, a holding claw portion formed to be contactable with another side wall of the flow passage block opposite to the one side wall, and a coupling mechanism configured to couple the plate portion and the holding claw portion, and the plate portion is formed with an insertion hole into which the holding claw portion of the clip attached to the adjacent fluid supply lines is allowed to be entered.

According to this aspect, even when a gap between fluid supply lines is narrow, a clip can be attached to a fluid supply line of a fluid supply device.

### BRIEF DESCRIPTION OF DRAWINGS

FIG. 1 is a perspective view showing a fluid supply device according to the present embodiment.

FIG. 2 is a schematic perspective view showing a state where heater-equipped clips are attached to fluid supply lines arranged side by side.

FIG. 3 is a schematic plan view showing a state where the heater-equipped clips are attached to the fluid supply lines arranged side by side.

FIG. 4 is a cross-sectional view taken along an IV-IV line in FIG. 3.

FIG. 5 is a perspective view showing a first member constituting a part of the heater-equipped clip.

FIG. 6 is a perspective view showing a second member constituting another part of the heater-equipped clip.

FIG. 7 is a front view of the second member.

FIG. 8 is a flowchart showing a method of attaching the heater-equipped clip.

### DESCRIPTION OF EMBODIMENTS

Hereinafter, an embodiment of the present invention (hereinafter, referred to as the present embodiment) will be described with reference to the accompanying drawings. In the present specification, the same elements are denoted by the same reference numerals throughout the whole.

### (Fluid Supply Device)

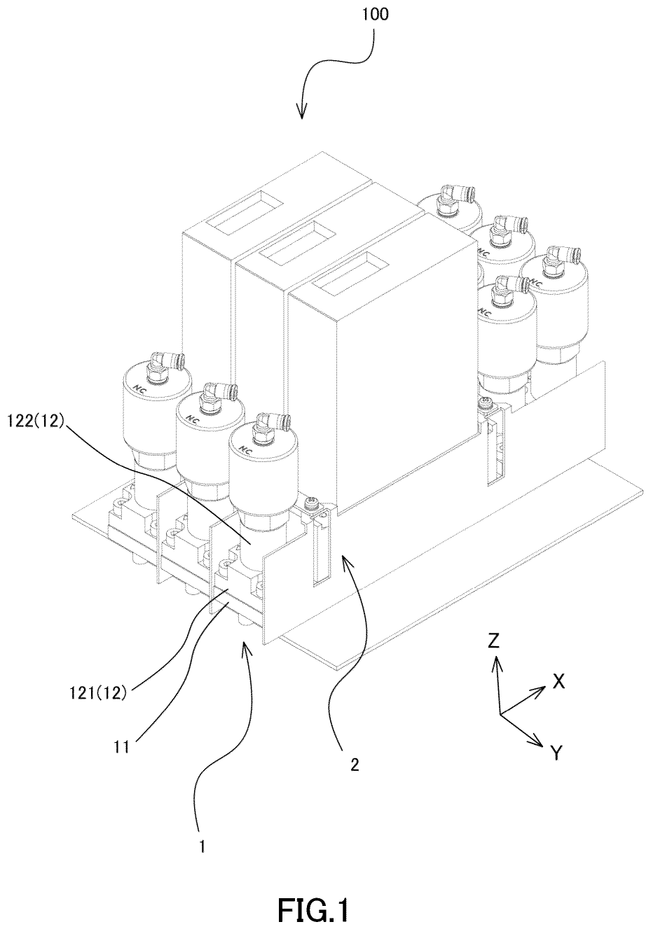

A fluid supply device 100 according to the present embodiment will be described with reference to FIG. 1.

FIG. 1 is a perspective view showing the fluid supply device 100 according to the present embodiment. In FIG. 1, a longitudinal direction, a width direction, and a height direction of the fluid supply device 100 orthogonal to each other are respectively taken as a direction along an X-axis, a direction along a Y-axis, and a direction along a Z-axis. Hereinafter, for convenience of description, the longitudinal direction, the width direction, and the height direction of the fluid supply device 100 are simply referred to as a longitudinal direction, a width direction, and a height direction.

The fluid supply device 100 according to the present embodiment is used as a process gas or a purge gas supply unit in which a semiconductor manufacturing device (a CVD apparatus, a sputtering apparatus, an etching apparatus, or the like) (not shown) is provided.

As shown in FIG. 1, the fluid supply device 100 includes a plurality of fluid supply lines 1 arranged side by side along the width direction and extending along the longitudinal direction, and a plurality of heater-equipped clips 2 attached (assembled) to the plurality of fluid supply lines 1.

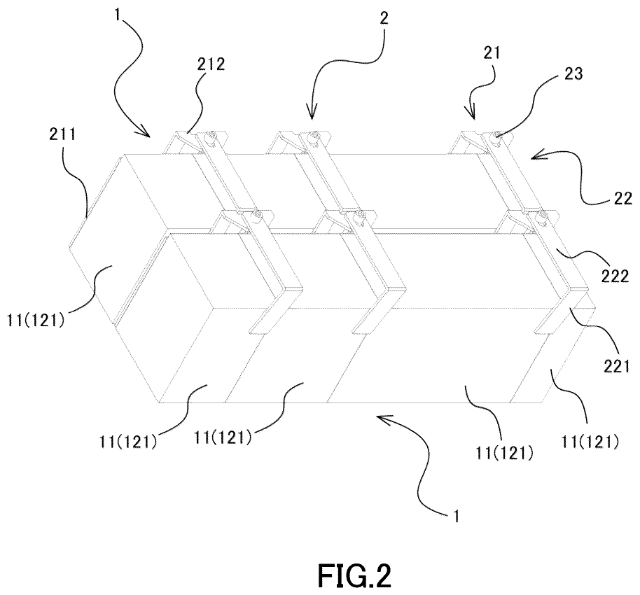

For example, the plurality of fluid supply lines 1 appropriately control a flow rate of a process gas as a gas to supply the process gas to the semiconductor manufacturing device. A slight gap is formed between adjacent fluid supply lines 1. In a gap between the adjacent fluid supply lines 1, a plate portion 211 (to be described later) of one heater-equipped clip 2 attached to one of the adjacent fluid supply lines 1, and a holding claw portion 221 (to be described later) of the other heater-equipped clip 2 attached to the other one of the adjacent fluid supply lines 1 are disposed so as not to interfere with each other (see FIGS. 2 to 7).

Each fluid supply line 1 includes base blocks 11 as a plurality of flow passage blocks arranged along the longitudinal direction, and a plurality of fluid devices 12 fixed to the plurality of base blocks 11 by bolting. The plurality of fluid devices 12 include, for example, an on-off valve, a regulator, a pressure gauge, and a mass flow controller. Each fluid device 12 includes a block portion 121 as a flow passage block coupled to the base block 11, and a fluid device main body 122 provided in the block portion 121. Here, the flow passage block is a block in which a flow passage through which a fluid flows is formed.

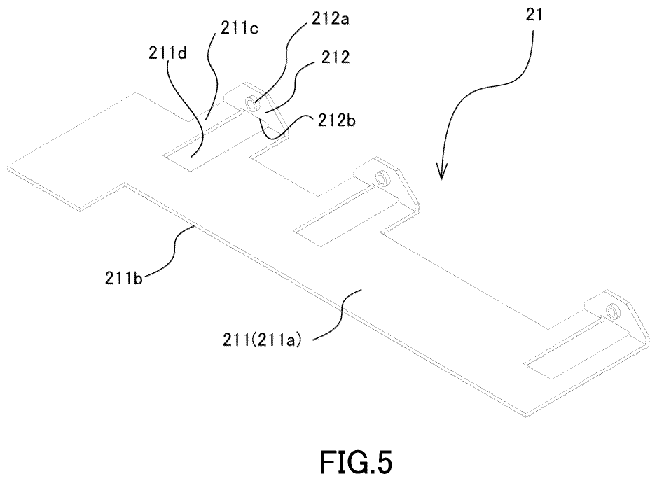

The heater-equipped clip 2 is a clip for transferring heat of an integrally formed heater 211b to the base block 11 and the block portion 121 of the fluid device 12 to prevent liquefaction of the process gas (see FIG. 5). Details of the heater-equipped clip 2 will be described later.

### (Heater-equipped Clip)

Next, the heater-equipped clip 2 according to the present embodiment will be described in detail with reference to FIGS. 1 to 7.

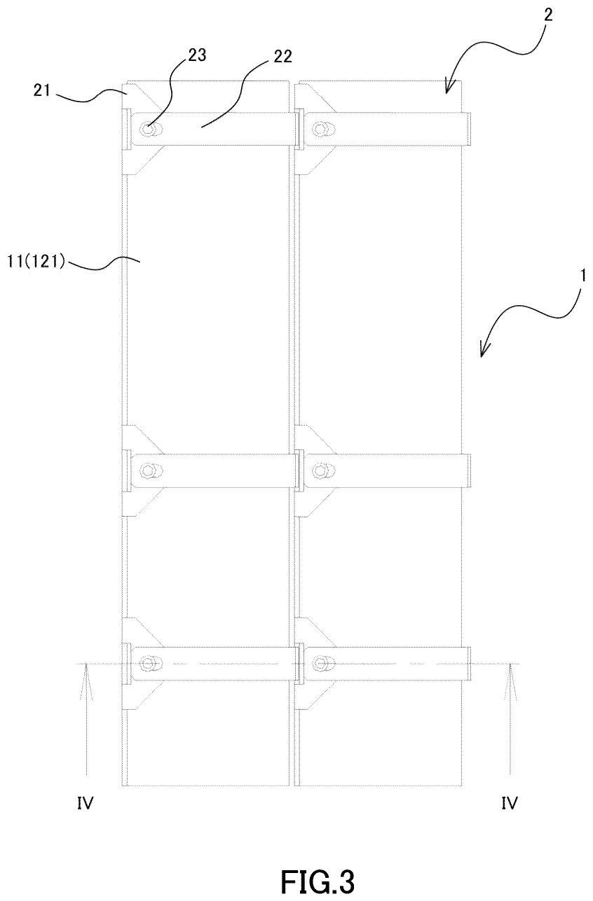

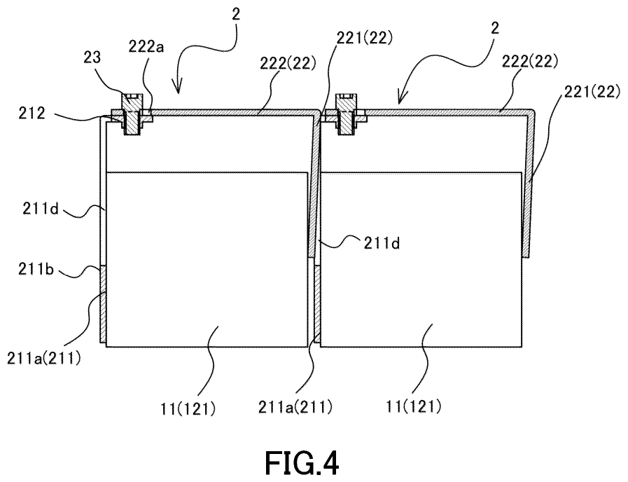

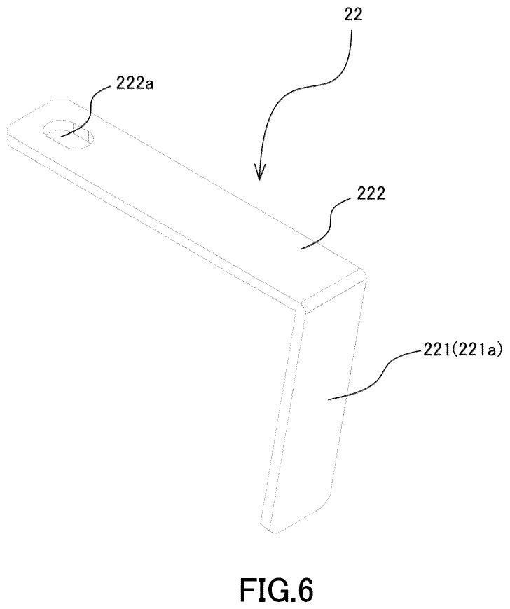

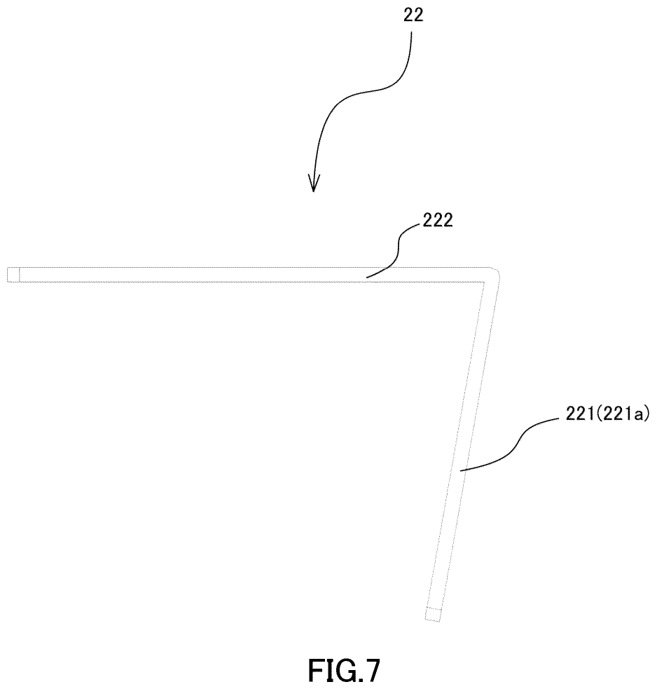

FIG. 2 is a schematic perspective view showing a state where the heater-equipped clip 2 is attached to fluid supply lines provided together. FIG. 3 is a schematic plan view showing a state where the heater-equipped clips 2 are attached to the fluid supply lines 1 arranged side by side. FIG. 4 is a cross-sectional view taken along an IV-IV line in FIG. 3. FIG. 5 is a perspective view showing a first member 21 constituting a part of the heater-equipped clip 2. FIG. 6 is a perspective view showing a second member 22 constituting another part of the heater-equipped clip 2. FIG. 7 is a front view of the second member 22. In FIGS. 2 to 4, the base block 11 and the block portion 121 are integrally formed, and the fluid device main body 122 is omitted. The heater-equipped clip 2 shown in FIG. 1 is only a part of the heater-equipped clip 2 shown in FIGS. 2 to 4.

As shown in FIGS. 1 to 7, the heater-equipped clip 2 according to the present embodiment includes the first member 21, the second member 22, and screws 23 that couple the first member 21 and the second member 22 to each other by screwing. The first member 21 (excluding a heater 211b) and the second member 22 are formed by bending a sheet metal.

The first member 21 includes the integrally formed plate portion 211 and a plurality of (here, three) first coupling pieces 212. On the other hand, the second member 22 includes an integrally formed holding claw portion 221 and a plurality of (here, three) second coupling pieces 222. In a state where the heater-equipped clip 2 is attached to the fluid supply line 1 (that is, in a state where the fluid supply line 1 is held by the heater-equipped clip 2), the plate portion 211 and the holding claw portion 221 that are coupled to a coupling mechanism including the first coupling pieces 212 and the second coupling pieces 222 sandwich both side walls of the base block 11 and the block portion 121.

The plate portion 211 includes a plate portion main body 211a, a heater 211b fixed to the plate portion main body 211a, a plurality of (here, three) protruding pieces 211c provided in the plate portion main body 211a, and a plurality of (here, three) insertion holes 211d formed in both the plate portion main body 211a and the protruding pieces 211c.

In the state where the heater-equipped clip 2 is attached to the fluid supply line 1 (that is, in the state where the fluid supply line 1 is held by the heater-equipped clip 2), the plate portion main body 211a is formed to be in surface contact with one side wall of the plurality of base blocks 11 and the block portion 121 which are arranged to extend along the longitudinal direction of the fluid supply line 1.

The heater 211b is provided on one side surface of the plate portion 211 (specifically, the plate portion main body 211a), and specifically includes a heating wire (not shown) and a protective film (not shown) covering the heating wire. In other words, the heater 211b and the plate portion main body 211a are integrally formed. Accordingly, a position of the heater 211b can be easily adjusted when the heater-equipped clip 2 is attached to the fluid supply line 1 (at the time of attachment) as compared with a clip separately formed from the heater.

In the present embodiment, in order to improve the thermal conductivity of the heater 211b, the heater 211b is provided on another side surface opposite to the one side surface of the plate portion 211 which is in surface contact with one side wall of the base block 11 and the block portion 121, but the present invention is not limited thereto. For example, the heater 211b may be interposed between the plate portion 211 (specifically, one side surface of the plate portion 211) and the base block 11 and the block portion 121 (specifically, one side wall of the base block 11 and the block portion 121).

The plurality of protruding pieces 211c are respectively formed integrally with the plurality of first coupling pieces 212. In other words, the plurality of first coupling pieces 212 are coupled to the plate portion main body 211a via the plurality of protruding pieces 211c. The plurality of protruding pieces 211c are provided to protrude from an upper end of the plate portion main body 211a at intervals along the longitudinal direction.

Here, an interval between adjacent protruding pieces 211c in the same fluid supply line 1 depends on a length of the fluid device 12 in the longitudinal direction. In other words, in the state where the heater-equipped clip 2 is attached to the fluid supply line 1 (that is, in the state where the fluid supply line 1 is held by the heater-equipped clip 2), the plurality of protruding pieces 211c are provided to be positioned at a boundary portion between the adjacent fluid devices 12 in the same fluid supply line 1 (that is, a boundary portion of the block portion 121/a region where the fluid device main body 122 is not provided).

In this state, the plate portion main body 211a does not protrude from an upper wall of the highest block portion 121, and the plurality of protruding pieces 211c are provided to protrude from the upper wall of the highest block portion 121. Accordingly, compared with a structure in which the plate portion main body 211a protrudes from the upper wall of the highest block portion 121, the heat of the heater 211b can be transferred to the base block 11 and the block portion 121 via the plate portion 211 without waste. Therefore, a heat transfer effect from the heater 211b to the base block 11 and the block portion 121 can be improved.

The plurality of insertion holes 211d are elongated holes formed in both the plurality of protruding pieces 211c (specifically, the entire region of the protruding piece 211c) and the plate portion main body 211a to extend along a height direction (protruding direction of the protruding piece 211c) orthogonal to the longitudinal direction of the plate portion main body 211a. Specifically, each insertion hole 211d is formed such that the holding claw portions 221 (specifically, holding claws 221a to be described later) of the heater-equipped clips 2 attached to the adjacent fluid supply lines 1 are allowed to be entered.

The plurality of first coupling pieces 212 constitute a part of a coupling mechanism that couples the plate portion 211 and the holding claw portions 221. The plurality of first coupling pieces 212 are formed by bending tip ends of the plurality of protruding pieces 211c by 90°.

In the state where the heater-equipped clip 2 is attached to the fluid supply line 1 (that is, in the state where the fluid supply line 1 is held by the heater-equipped clip 2), the plurality of first coupling pieces 212 are integrally formed with the plate portion 211 so as to face the upper wall of the block portion 121.

A plurality of (here, three) screw holes 212a to be screwed with the plurality of screws 23 are formed in the plurality of first coupling pieces 212, respectively. The screw holes 212a are subjected to burring. The plurality of first coupling pieces 212 are respectively formed with a plurality of notches 212b communicating with the plurality of insertion holes 211d.

In the present embodiment, the plurality of first coupling pieces 212 are respectively coupled to the plate portion main body 211a via the plurality of protruding pieces 211c, but the present invention is not limited thereto. For example, the plurality of first coupling pieces 212 may be directly coupled to the upper end of the plate portion main body 211a without the plurality of protruding pieces 211c. In this case, the plurality of insertion holes 211d are formed only in the plate portion main body 211a.

The holding claw portion 221 includes a plurality of (here, three) holding claws 221a. In the state where the heater-equipped clip 2 is attached to the fluid supply line 1 (that is, in the state where the fluid supply line 1 is held by the heater-equipped clip 2), the plurality of holding claws 221a are holding pieces arranged at intervals in the longitudinal direction of the fluid supply line 1. In other words, the plurality of holding claws 221 a are provided to be in contact with another side wall of the boundary portion between the adjacent fluid devices 12 in the same fluid supply line 1 (that is, the boundary portion of the block portions 121/the region where the fluid device main body 122 is not provided). A heater is not fixed to each of the holding claws 221a.

The plurality of second coupling pieces 222 constitute another portion of a coupling mechanism that couples the plate portion 211 and the holding claw portions 221 (the holding claws 221a). The plurality of second coupling pieces 222 are formed by bending tip ends of the plurality of holding claws 221a. The holding claw 221a is an elastic material formed to be changeable in angle with the second coupling piece 222. When the holding claw 221a is not elastically deformed, an acute angle is formed between the second coupling piece 222 and the holding claw 221a (see FIG. 7).

In the state where the heater-equipped clip 2 is attached to the fluid supply line 1 (that is, in the state where the fluid supply line 1 is held by the heater-equipped clip 2), the plurality of second coupling pieces 222 are integrally formed with the plate portion 211 so as to face the upper wall of the block portion 121. Specifically, the plurality of first coupling pieces 212 and the plurality of second coupling pieces 222 are formed to face the upper wall of the block portion 121 so as to be separated from an upper wall of the boundary portion between the adjacent fluid devices 12 (that is, the boundary portion of the block portions 121/a region where the fluid device main body 122 is not provided) in the same fluid supply line 1. Accordingly, it is possible to avoid interference between the plurality of first coupling pieces 212 (or the plurality of second coupling pieces 222) and bolts tightened to the upper wall of the fluid device 12.

A plurality of (here, three) elongated holes 222a through which a plurality of screws 23 can penetrate are formed at end portions of the plurality of second coupling pieces 222 that are spaced apart from the holding claws 221a. These elongated holes 222a are formed to extend along the width direction (an extending direction of the second coupling pieces 222). Each screw 23 passes through each elongated hole 222a of each second coupling piece 222 and is screwed into each screw hole 212a of each first coupling piece 212, so that the plate portion 211 and the holding claw portion 221 can be coupled more easily to the coupling mechanism.

In the present embodiment, in order to adjust a position of the second member 22 with respect to the first member 21 in the width direction, the elongated hole 222a is formed in the second coupling piece 222, but the present invention is not limited thereto. For example, a circular hole may be formed in the second coupling piece 222.

In the present embodiment, the screw hole 212a and the elongated hole 222a are respectively formed in the first coupling piece 212 and the second coupling piece 222, but the present invention is not limited thereto. The screw hole 212a and the long hole 222a may be respectively formed in the second coupling piece 222 and the first coupling piece 212. In other words, the screw hole 212a may be formed in one of the first coupling piece 212 and the second coupling piece 222, and the elongated hole 222a may be formed in the other of the first coupling piece 212 and the second coupling piece 222.

In the state where the heater-equipped clip 2 is attached to the fluid supply line 1 (that is, in the state where the fluid supply line 1 is held by the heater-equipped clip 2), the holding claw 221a is elastically deformed, and an angle formed between the second coupling piece 222 and the holding claw 221 a is widened to be substantially 90°. As shown in FIG. 4, in this state, the holding claw 221a is formed such that a length thereof is shorter than a length of the insertion hole 211d. Accordingly, when the heater-equipped clip 2 is attached to each of the adjacent fluid supply lines 1, the insertion hole 211d (or both of the insertion hole 211d and the notch 212b) of the plate portion 211 of one of the heater-equipped clips 2 disposed in the gap between the adjacent fluid supply lines 1 accommodates the holding claw 221a of the other heater-equipped clip 2. In other words, the plate portion 211 of one of the adjacent heater-equipped clips 2 and the holding claw 221a of another of the adjacent heater-equipped clips 2 can be disposed so as not to interfere with each other in the gap between the adjacent fluid supply lines 1. As a result, even when the gap between the adjacent fluid supply lines 1 is narrow (specifically, even when the gap between the adjacent fluid supply lines 1 is wider than a thickness of the plate portion 211 and is narrower than a total thickness of the thickness of the plate portion 211 and a thickness of the holding claw 221a), the adjacent heater-equipped clips 2 can be respectively attached to the adjacent fluid supply lines 1.

Further, in this case, since another side wall of one of the base block 11 and the block portion 121 in the gap between the adjacent fluid supply lines 1 is heated by the heater 211b of the plate portion 211 of another of the heater-equipped clips 2 attached to the adjacent fluid supply lines 1 (the base block 11 and the block portion 121), the one of the base block 11 and the block portion 121 can be efficiently heated (kept warm).

As described above, in the heater-equipped clip 2 according to the present embodiment, the heater 211b is fixed only to the plate portion 211 (specifically, the plate portion main body 211a) without being fixed to the holding claw portion 221, and thus the gap between the adjacent fluid supply lines 1 can be narrowed as compared with a fluid supply device using a heater fixture in which two heaters are held between both side walls of the base block 11 and the block portion 121. As a result, even when the gap between the fluid supply lines 1 is narrow, the heater-equipped clip 2 can be attached to the fluid supply line 1.

Further, by separately forming the first coupling pieces 212 integrally formed with the plate portion 211 and the second coupling pieces 222 integrally formed with the holding claw portion 221, the heater-equipped clip 2 can be easily attached to the fluid supply line 1 as compared with a clip in which the plate portion 211, the holding claw portion 221, and the coupling mechanism that couples the plate portion 211 and the clamping claw portion 221 are integrally formed.

### (Method of Attaching Heater-equipped Clip)

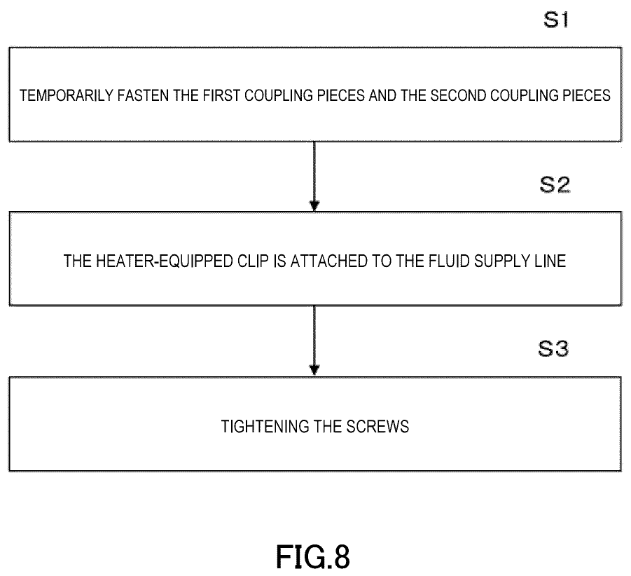

Next, a method of attaching the heater-equipped clip 2 will be described with reference to FIG. 8.

FIG. 8 is a flowchart showing the method of attaching the heater-equipped clip 2.

As shown in FIG. 8, first, in step S1, the first coupling pieces 212 integrally formed with the plate portion 211 to which the heater 211b is fixed and the second coupling pieces 222 integrally formed with the holding claw portion 221 are temporarily fastened (coupled) by screw screwing.

Next, in step S2, the heater-equipped clip 2 is attached to the fluid supply line 1 such that the plate portion 211 comes into contact with one side wall of the base block 11 and the block portion 121 of the fluid supply line 1 and the holding claw portion 221 comes into contact with another side wall of a boundary portion between the adjacent fluid devices 12 (that is, a boundary portion between the block portions 121) of the fluid supply line 1.

Next, in step S3, a position of the holding claw portion 221 (a second member 22) with respect to the plate portion 211 (a first member 21) is adjusted as necessary.

Finally, in step S4, by tightening the screws 23, the fluid supply line 1 is securely held by the heater-equipped clip 2.

### (Functions And Effects)

Next, functions and effects of the present embodiment will be described.

The heater-equipped clip 2 according to the present embodiment is a clip attached to each of the plurality of fluid supply lines 1 which are arranged side by side in the fluid supply device 100 and each include the plurality of base blocks 11. The heater-equipped clip 2 includes the plate portion 211 including a fixed heater 211b and formed to be surface-contactable with one side wall of the base block 11, the holding claw portion 221 formed to be contactable with another side wall of the base block 11 opposite to the one side wall, and a coupling mechanism configured to couple the plate portion 211 and the holding claw portion 221. The plate portion 211 is formed with the insertion holes 211d into which the holding claws 221a of the heater-equipped clips 2 attached to the adjacent fluid supply lines 1 are allowed to be entered.

The fluid supply device 100 according to the present embodiment includes a plurality of fluid supply lines 1 which are arranged side by side and each include the plurality of base blocks 11, and the plurality of heater-equipped clips 2 attached to the plurality of fluid supply lines 1, respectively. Each of the heater-equipped clips 2 includes the plate portion 211 including integrally formed heater 211b and formed to be surface-contactable with one side wall of the base block 11, the holding claw portion 221 formed to be contactable with another side wall of the base block 11 opposite to the one side wall, and a coupling mechanism configured to couple the plate portion 211 and the holding claw portion 221. The plate portion 211 is formed with the insertion holes 211d into which the holding claw portions 221 of the heater-equipped clips 2 attached to the adjacent fluid supply lines 1 are allowed to be entered.

According to this configuration, since the heater 211b is fixed only to the plate portion 211 (specifically, the plate portion main body 211a) without fixing the heater 211b to the holding claw portion 221, the gap between the adjacent fluid supply lines 1 can be narrowed as compared with the fluid supply device using a heater fixture in which two heaters are held between both side walls of the base block 11. As a result, even when the gap between the fluid supply lines 1 is narrow, the heater-equipped clip 2 can be attached to the fluid supply line 1.

Further, since the plate portion 211 includes the fixed heater 211b, that is, since the heater 211b and the plate portion 211 are integrally formed, the position of the heater 211b can be easily adjusted when the heater-equipped clip 2 is attached to the base block 11 of the fluid supply line 1 (at the time of attachment) as compared with a clip formed separately from the heater.

Further, when the heater-equipped clip 2 is attached to each of the adjacent fluid supply lines 1, the holding claw 221a of the other heater-equipped clip 2 is accommodated in the insertion hole 211d of the plate portion 211 of one of the heater-equipped clips 2 disposed in the gap between the adjacent fluid supply lines 1. In other words, the plate portion 211 of one of the adjacent heater-equipped clips 2 and the holding claw 221a of another of the adjacent heater-equipped clips 2 can be disposed so as not to interfere with each other in the gap between the adjacent fluid supply lines 1. As a result, even when the gap between the adjacent fluid supply lines 1 is narrow (specifically, even when the gap between the adjacent fluid supply lines 1 is wider than a thickness of the plate portion 211 and is narrower than the total thickness of the thickness of the plate portion 211 and the thickness of the holding claw 221a), the adjacent heater-equipped clips 2 can be respectively attached to the adjacent fluid supply lines 1.

In the present embodiment, the coupling mechanism includes the first coupling pieces 212 integrally formed with the plate portion 211 to be able to face the upper wall of the block portion 121, and the second coupling pieces 222 integrally formed with the holding claw portions 221 to be able to face the upper wall of the block portion 121. The first coupling piece 212 and the second coupling pieces 222 are coupled by screwing.

According to this configuration, by separately forming the first coupling pieces 212 integrally formed with the plate portion 211 and the second coupling pieces 222 integrally formed with the holding claw portion 221, the heater-equipped clip 2 can be easily attached to the fluid supply line 1 as compared with a clip in which the plate portion 211, the holding claw portion 221, and the coupling mechanism that couples the plate portion 211 and the clamping claw portion 221 are integrally formed.

In the present embodiment, the screw hole 212a is formed in one of the first coupling piece 212 and the second coupling piece 222, and the elongated hole 222a extending along the width direction of the base block 11 is formed in another of the first coupling piece 212 and the second coupling piece 222.

According to this configuration, since the screw 23 can slide in the elongated hole 222a, the position of the holding claw portion 221 with respect to the plate portion 211 can be adjusted as necessary.

In the present embodiment, the plate portion 211 is formed to be surface-contactable with one side wall of the plurality of base blocks 11 which are arranged to extend along the longitudinal direction of the fluid supply line 1, and the holding claw portion 221 has a plurality of holding claws 221a arranged at intervals in the longitudinal direction of the fluid supply line 1.

Further, in the present embodiment, the coupling mechanism includes the plurality of first coupling pieces 212 arranged at intervals in the longitudinal direction of the fluid supply line 1 and integrally formed with the plate portion 211 so as to be able to face the upper wall of the block portion 121, and the plurality of second coupling pieces 222 arranged at intervals in the longitudinal direction of the fluid supply line 1 and integrally formed with the holding claw portions 221 so as to be able to face the upper wall of the block portion 121. The plurality of holding claws 221a are in contact with the respective other side walls of the boundary portions between the adjacent block portions 121 on the same fluid supply line 1, and the plurality of first coupling pieces 212 respectively correspond to the plurality of second coupling pieces 222 and face the upper walls of the boundary portions of the adjacent block portions 121 in the same fluid supply line 1.

According to this configuration, the heater-equipped clip 2 can be easily attached to the fluid supply line 1, and interference between the plurality of first coupling pieces 212 (or the plurality of second coupling pieces 222) and bolts fastened to the fluid device 12 can be avoided.

Further, in the present embodiment, one side surface of the plate portion 211 is formed to be surface-contactable with one side wall of the base block 11, and the heater 211b is fixed to another side surface of the plate portion 211.

According to this configuration, the thermal conductivity of the heater 211b can be improved as compared with a structure in which the heater 211b is interposed between the plate portion 211 and the base block 11.

Further, in the present embodiment, the plate portion 211 of one of the adjacent heater-equipped clips 2 and the holding claw portion 221 of another of the adjacent heater-equipped clips 2 can be disposed so as not to interfere with each other in the gap between the adjacent fluid supply lines 1.

Although the embodiment of the present invention has been described above, the above embodiment merely exemplifies application examples of the present invention and does not intend to limit the technical scope of the present invention to the specific configurations of the above embodiment.

The present application claims a priority of Japanese Patent Application No. 2023-051366 filed with the Japan Patent Office on Mar. 28, 2023, all the contents of which are hereby incorporated by reference.

1. A clip attached to each of a plurality of fluid supply lines which are arranged side by side in a fluid supply device and each include a plurality of flow passage blocks, the clip comprising:
a plate portion including a fixed heater and formed to be surface-contactable with one side wall of the flow passage block;
a holding claw portion formed to be contactable with another side wall of the flow passage block opposite to the one side wall; and
a coupling mechanism configured to couple the plate portion and the holding claw portion, wherein
the plate portion is formed with an insertion hole into which the holding claw portion of the clip attached to the adjacent fluid supply lines is allowed to be entered.

2. The clip according to claim 1, wherein
the coupling mechanism includes
a first coupling piece integrally formed with the plate portion to be able to face an upper wall of the flow passage block, and
a second coupling piece integrally formed with the holding claw portion to be able to face the upper wall of the flow passage block, and
the first coupling piece and the second coupling piece are coupled to each other by screw screwing.

3. The clip according to claim 2, wherein
a screw hole is formed in one of the first coupling piece and the second coupling piece, and
an elongated hole extending along a width direction of the flow passage block is formed in another of the first coupling piece and the second coupling piece.

4. The clip according to claim 1, wherein
the plate portion is formed to be surface-contactable with the one side wall of each of the plurality of flow passage blocks which are arranged to extend along a longitudinal direction of the fluid supply line, and
the holding claw portion has a plurality of holding claws arranged at intervals in the longitudinal direction of the fluid supply line.

5. The clip according to claim 4, wherein
the coupling mechanism includes
a plurality of first coupling pieces arranged at intervals in the longitudinal direction of the fluid supply line and integrally formed with the plate portion to be able to face an upper wall of the flow passage block, and
a plurality of second coupling pieces arranged at intervals in the longitudinal direction of the fluid supply line and integrally formed with the holding claw portion to be able to face the upper wall of the flow passage block,
the plurality of holding claws are in contact with the other side walls of boundary portions between adjacent flow passage blocks along the same fluid supply line, and
the plurality of first coupling pieces respectively correspond to the plurality of second coupling pieces, and face the upper walls of the boundary portions between adjacent flow passage blocks along the same fluid supply line.

6. The clip according to claim 1, wherein
the plate portion is formed such that one side surface thereof is surface-contactable with the one side wall of the flow passage block, and
the heater is fixed to another side surface of the plate portion.

7. A fluid supply device comprising:
a plurality of fluid supply lines arranged side by side and each including a plurality of flow passage blocks; and
a plurality of clips attached to the plurality of fluid supply lines, respectively, wherein
each of the plurality of clips includes
a plate portion including an integrally formed heater and formed to be surface-contactable with one side wall of the flow passage block,
a holding claw portion formed to be contactable with another side wall of the flow passage block opposite to the one side wall, and
a coupling mechanism configured to couple the plate portion and the holding claw portion, and
the plate portion is formed with an insertion hole into which the holding claw portion of the clip attached to the adjacent fluid supply lines is allowed to be entered.

8. The fluid supply device according to claim 7, wherein
the plate portion of one of the adjacent clips and the holding claw portion of another of the adjacent clips do not interfere with each other in a gap between the adjacent fluid supply lines.
